(19) United States
(12) Patent Application Publication
(10) Pub. No.: US 2026/0226652 A1
(43) Pub. Date: Aug. 6, 2026

(54) A METHOD OF FORMING A GRAPHENE LAYER STRUCTURE AND A GRAPHENE SUBSTRATE

(71) Applicant: PARAGRAF LIMITED, Somersham (GB)

(72) Inventors: Sebastian Dixon, Somersham (GB); Ivor Guiney, Somersham (GB)

(73) Assignee: PARAGRAF LIMITED, Somersham (GB)

(21) Appl. No.: 19/129,839

(22) PCT Filed: Aug. 23, 2023
(86) PCT No.: PCT/EP2023/073131

§ 371 Date: May 14, 2025

(30) Foreign Application Priority Data
Nov. 15, 2022 (GB) 2217046.8
Jan. 24, 2023 (GB) 2300996.2

(51) Int. Cl. C30B 25/18; C30B 25/10; C30B 25/12; C30B 25/14; C30B 29/02; C30B 29/16

(52) U.S. Cl. CPC C30B 25/183; C30B 25/10; C30B 25/12; C30B 25/14; C30B 29/02; C30B 29/16

(57) ABSTRACT

The present invention relates to a method of forming a graphene layer structure, the method comprising: providing a growth substrate comprising a first layer on a support layer; and forming a graphene layer structure on a growth surface of the first layer by CVD; wherein the first layer is formed of scandium oxide.

The present invention relates to a method of forming a graphene layer structure, in particular by CVD on scandium oxide. The present invention also provides a graphene substrate, in particular wherein a graphene layer structure is directly on a first layer formed of scandium oxide.

Graphene has received much attention as a two-dimensional material in view of its unique electronic properties and its applications in electronic devices. It is common in the art for graphene to be manufactured by techniques such as exfoliation or by CVD on catalytic metal substrates such as copper. The graphene produced by such methods is then transferred to electronic devices having compatible, insulative or semiconducting substrates.

It is also known in the art that graphene may be synthesised, manufactured or formed, directly on non-metallic surfaces of substrates. These include silicon, sapphire and III-V semiconductor substrates. The present inventors have found that the most effective method for manufacturing high quality graphene, especially directly on such non-metallic surfaces, is that disclosed in WO 2017/029470 (the contents of which is incorporated herein by reference in its entirety). This publication discloses methods for manufacturing graphene; principally these rely on heating a substrate held within a reaction chamber to a temperature that is within a decomposition range of a carbon based precursor for graphene growth, introducing the precursor into the reaction chamber through a relatively cool inlet so as to establish a sufficiently steep thermal gradient that extends away from the substrate surface towards the point at which the precursor enters the reaction chamber such that the fraction of precursor that reacts in the gas phase is low enough to allow the formation of graphene from carbon released from the decomposed precursor. Preferably the apparatus comprises a showerhead having a plurality of precursor entry points or inlets, the separation of which from the substrate surface may be varied and is preferably less than 100 mm. The method of WO 2017/029470 is ideally performed using an MOCVD reactor. GB 2570127 relates to a method of making a graphene layer structures using the method of WO 2017/029470 in which at a sufficient layer thickness, the multilayer graphene layer structure delaminates intact from the substrate to produce an unsupported graphene layer structure.

Whilst the method of WO 2017/029470 enables the production of high quality graphene with excellent uniformity and a constant number of layers (as desired) across its whole area on the substrate without additional carbon fragments or islands, the strict requirements in the art of electronic device manufacture means that there remains a need to further improve the electronic properties of the graphene and to provide methods that are more reliable and more efficient for the industrial manufacture of graphene, particularly large area graphene on non-metallic substrates.

WO 2022/200351 (the contents of which is incorporated herein by reference in its entirety), as well as the corresponding GB 2605211, GB 2607410 and TW 111111013, is a publication originating from the present inventors which also aims to address this problem and discloses forming a graphene layer structure on a growth surface of a substrate by CVD, wherein the growth surface is formed of a material selected from the group consisting of: YSZ, MgAl₂O₄, YAlO₃, CaF₂, and LaF₃.

WO 2022/175273 (the contents of which is incorporated herein by reference in its entirety), as well as the corresponding GB 2603905 and TW 202246175, is a publication originating from the present inventors which relates to the formation of a thin graphene-containing conductive substrate obtainable by etching a sacrificial silicon wafer away from a graphene layer structure formed on an insulative layer that is itself formed on the silicon wafer.

However, there remains a need in the art for methods which provide yet further higher quality graphene so as to provide improved electronic properties characteristic of those which are envisaged as theoretically possible for graphene. Moreover, there is a need in the art for methods which allow for the integration of graphene into conventional silicon-based semiconductor manufacturing processes and the growth of graphene onto silicon-based wafers/substrates.

In accordance with a first aspect of the present invention, there is provided a method of forming a graphene layer structure, the method comprising:
providing a growth substrate comprising a first layer on a support layer; and
forming a graphene layer structure on a growth surface of the first layer by CVD;
wherein the first layer is formed of scandium oxide.

In a further aspect there is provided a graphene substrate comprising a CVD-grown graphene layer structure grown directly on a first layer of a growth substrate, wherein the growth substrate comprises the first layer on a support layer, and wherein the first layer is formed of scandium oxide.

The present disclosure will now be described further. In the following passages, different aspects/embodiments of the disclosure are defined in more detail. Each aspect/embodiment so defined may be combined with any other aspect/embodiment or aspects/embodiments unless clearly indicated to the contrary. In particular, any feature indicated as being preferred or advantageous may be combined with any other feature or features indicated as being preferred or advantageous. As such, the method of forming a graphene layer structure preferably results in the graphene substrate described herein, and vice versa, the graphene substrate is preferably obtainable by the method.

The present invention relates to a method of forming a graphene layer structure by CVD growth of graphene on a growth surface of a substrate (which may be referred to as a growth substrate). The method thereby forms a graphene substrate and accordingly, the present invention also provides a graphene substrate per se. Forming may be considered synonymous with synthesising, manufacturing, producing, depositing and growing. Graphene is a very well-known two-dimensional material referring to an allotrope of carbon comprising a single layer of carbon atoms in a hexagonal lattice. Graphene, as used herein, refers to one or more layers of graphene. Accordingly, the present invention relates to the formation of a monolayer of graphene as well as multilayer graphene (either of which may be termed a graphene layer structure). Graphene, as used herein, refers to a graphene layer structure, preferably having from 1 to 10 monolayers of graphene. In many subsequent applications of a graphene substrate, one monolayer of graphene is particularly preferred. Accordingly, the graphene layer structure is preferably a graphene monolayer. Nevertheless, multilayer graphene may be preferable for certain applications and 2 or 3 layers of graphene may be preferred. As described herein, the method of forming a graphene layer structure comprises forming graphene by CVD directly onto a growth surface of a first layer formed of scandium oxide (i.e. Sc₂O₃, though it will be appreciated that the stoichiometry may vary about the ideal ratio). The inventors were surprised to find that very high quality of graphene can be obtained by CVD growth on scandium oxide, even with minimal optimisation of routine growth parameters.

A graphene substrate will be understood as a substrate comprising graphene and suitable for subsequent use. Particularly, the graphene substrate is suitable for use in preparing graphene based electronic devices. As used herein, the term substrate may be used to refer to a material suitable for the deposition of another layer thereon. The term substrate is typically synonymous with a wafer. Preferably the graphene provides the surface on which a further layer is to be deposited.

The method comprises providing a growth substrate wherein the growth substrate comprises a first layer and a support layer, the first layer being on the support layer and having an opposite exposed surface suitable for forming such further layers, specifically a graphene layer structure by CVD thereon. Such a surface of the first layer is referred to herein as the growth surface. Substrates suitable for the growth of layers on their surface are well known. Substrates may also be referred to in the art as wafers and may consist of a single material or layers of multiple materials. As will be appreciated, a substrate, and a growth surface thereof, is formed of crystalline material as is known in the art. Accordingly, substrates and wafers provide a planar growth surface, preferably formed of a single crystal, and do not include powders or nano-crystalline materials. Typically, substrates have a diameter of at least 1 inch (25 mm), preferably at least 2 inches (51 mm). Substrates up to 6″ (15 cm) and 12″ (30 cm) are also available.

The present invention in particular provides a solution to the problem with integration of graphene into silicon-based manufacturing processes. Accordingly, it is most preferred that the support layer comprises silicon, though other support layers such as sapphire may be used. A silicon support layer, includes a “pure” silicon wafer (essentially consisting of silicon, doped or undoped) or what may be referred to as a CMOS wafer which includes additional associated circuitry. The thickness of the support layer (which may also be referred to herein as a “first” substrate) is generally much thicker that the thickness of the first layer thereon. Typically, the support layer has a thickness of 250 μm to 1.5 mm, for example from 400 μm to 1 mm. On the other hand, the thickness of the first layer of such a substrate is substantially thinner. Preferably, the thickness is at least 2 nm, preferably at least 5 nm and/or less than 500 nm, preferably less than 100 nm. Suitable ranges for the thickness of the first layer are preferably 5 nm to 100 nm, preferably 10 to 50 nm. In some embodiments, very thin layers are preferred and the thickness of the layer may preferably be from 2 nm to 10 nm. In some embodiments, there is no intervening native silicon oxide which may be removed from the surface of a silicon support before forming the first layer.

Preferably, the growth substrate is provided in the first step of the method by forming the first layer (i.e. scandium oxide) by epitaxy on a first substrate. The first substrate comprises the support layer and, optionally, a buffer layer. Preferably, the first substrate consists of the support layer and the optional buffer layer.

For example, in some preferred embodiments, the method comprises forming a scandium oxide layer by epitaxy directly on a silicon wafer. In another preferred embodiment, the first substrate consists of a silicon wafer (support layer) having directly thereon a buffer layer and the method comprises forming a scandium oxide layer by epitaxy directly on the buffer layer. Preferably, the buffer layer is formed by epitaxy on the support layer.

Suitable methods for epitaxy are well-known to those skilled in the art. Preferred methods of epitaxy include molecular beam epitaxy (MBE) and sputtering, in particular high temperature sputtering. Such methods of epitaxy typically employ high temperatures, for example, from about 500° C. to about 1000° C.

A buffer layer is particularly suitable for embodiments wherein the support layer comprises silicon. The inventors have also found by X-ray diffraction that scandium oxide formed on a buffer layer is more strained than scandium oxide grown directly on a support, in particular silicon. Without wishing to be bound by theory, it is believed that buffer layers formed of oxides such as yttrium and erbium oxide are closely lattice-matched to silicon enabling “commensurate” cube-on-cube epitaxy as opposed to “coincident” or “domain matched” epitaxy for strongly mismatched scandium oxide. This results in strain in the scandium oxide on the buffer, rather than being relaxed when formed directly on a support. It is believed that the strain in the scandium oxide layer helps to avoid, or even prevent, <110> texturing from occurring during graphene formation which reduces the density of scattering sites. Since there is only a slight difference in surface energy between the <111> and <110> surfaces, the inventors have found that during graphene growth by CVD, the interaction of the carbon precursor with the oxygen-terminated <111> surface is believed to result in some oxygen removal (i.e. reduction) and therefore the surface energy rises providing a preference for a reconstruction to the next lowest energy termination of <110> which is observed as texturing of the growth surface. Such texturing ultimately impedes graphene growth and the electrical properties of the resulting graphene. By including a buffer layer, the increased strain in the scandium oxide layer favours maintenance of the <111> surface, reducing, or even eliminating, <110> texturing. As a result, graphene with a lower defect density and therefore better carrier transport properties can be achieved. For these reasons, a thin first layer of scandium oxide may be preferred since thicker layers are believed to result in reduced strain.

A buffer layer may help to mitigate the differences in lattice parameters and reduce the risk of forming defects in the first layer. For example, a buffer layer may help to annihilate or block threading dislocations, resulting in a reduced leakage current. A buffer layer is an inorganic cubic material, generally a metal oxide, though CaF₂ and MgF₂ may also be preferred. Suitable metal oxides include zirconium, yttrium, hafnium, cerium, erbium, gadolinium, dysprosium, praseodymium and/or magnesium oxide, strontium titanate (STO) and/or yttria-stabilised zirconia (YSZ). Particularly preferred oxides for forming the buffer oxide layer are erbium oxide, yttrium oxide, zirconium oxide and/or yttria-stabilised zirconia, preferably erbium oxide, yttrium oxide and/or YSZ, due to their thermodynamic stability during subsequent CVD growth of graphene.

Without wishing to be bound by theory, the ZrO₂ or YSZ interface with Si is believed to be less chemically stable than the Er₂O₃, Y₂O₃ or Sc₂O₃ interface with Si due to a greater driving force for the formation of secondary phases, e.g. silicides such as ZrSi or silicates such as ZrSiO₄, providing an advantage for erbium and/or yttrium oxide as a buffer layer, particularly as the layer directly on the silicon in the case of a multilayer buffer layer. Indeed, it is also a particular advantage of the invention wherein the scandium oxide is directly on the silicon support layer since the inventors have found that interface between scandium oxide and silicon is the most chemically stable. It is also believed that scandium oxide deposited directly on silicon as described herein may form an interface of scandium suboxide mitigating the differences in lattice parameter allowing for high crystal quality and/or a 7×7 reconstruction of the silicon heated under vacuum with the oxide removed produces a silicon surface with a different effective unit cell dimensional which may match better with scandium oxide. Erbium oxide has an advantage over other oxides in that it has better thermodynamic stability on silicon while being about the same in terms of lattice matching. One problem with erbium oxide is that it is strongly paramagnetic unlike other oxides which can be a problem for the intended final electronic device manufactured from the resulting graphene substrate. This potential issue may be mitigated by using a thin layer of erbium oxide, such as less than 10 nm, preferably less than 5 nm, for example about 2 nm.

In some preferred embodiments, the buffer layer consists of a single material. Of secondary consideration is the lattice mismatch between silicon and the buffer layer material. For example, YSZ has a small lattice mismatch between both silicon and scandium oxide. That is, the lattice constant for silicon is 5.43 Å and the lattice constant for scandium oxide is 9.85 Å (where half of the lattice constant is about 4.93 Å). The lattice constant for zirconium oxide is 5.15 Å, and YSZ is about 5.13 Å (depending on the extent of yttria doping), which give rise to an even lattice mismatch between silicon and scandium oxide of about 5% and about 4%, respectively. The corresponding mismatches for yttrium oxide (which has a lattice constant of 5.30 Å) are about 2% and about 7%. However, the inventors have found that pure binary zirconium oxide can be unstable to phase changes between its cubic and tetragonal phases at the temperatures desired for CVD growth of graphene. YSZ is also less thermodynamically stable than the other preferred rare earth oxides (Er, Y and Sc) and therefore YSZ buffer layers may not be suitable at very high graphene deposition temperatures, e.g. above 1,250° C. It is believed that by using a very thin layer of zirconium oxide (or YSZ), e.g. less than 10 nm, preferably less than 5 nm, more preferably less than 2 nm, the zirconium oxide layer is advantageously more resistant to phase changes. Combinations of these oxides may be used, for example a layer of yttrium oxide may be formed on the silicon, followed by a layer of zirconium oxide or YSZ to form a multilayer buffer layer. Buffer layers can have a drawback in that multiple layers having different thermal stabilities and coefficients of expansion can increase the risk of delamination.

In some embodiments, the buffer layer comprises a plurality of layers with decreasing amounts of Y form the interface with the silicon support to the interface with the first layer. For example, a buffer layer may comprise two sub-layers with a Y-rich sub-layer (e.g. Zr-poor and/or Sc-poor) on the silicon support, followed by a Y-poor sub-layer (e.g. Zr-rich and/or Sc-rich) and then the first layer formed of scandium oxide. In embodiments, the atomic ratio of Y to Zr and/or Sc (Y:Zr/Sc) adjacent the interface with the silicon support layer is greater than 1:1, preferably greater than 2:1, more preferably greater than 5:1, and even more preferably greater than 10:1. Additionally, the Y:Zr/Sc ratio adjacent the interface with the first layer is preferably less than 1:1, preferably less than 1:2, more preferably less than 1:5, and even more preferably less than 1:10. As will be appreciated, further sub-layers may be employed to provide a decreasing concentration of Y from the interface with silicon to the interface with the first layer. For example, in an embodiment, the Y:Zr/Sc ratio mid-way between the two interfaces may be about 1:1. Such multi-layer buffer layers may help to reduce the risks associated with delamination due to the reduced differences in thermal properties between each sub-layer.

Thus, in another embodiment, the buffer layer comprises a continuously graded composition wherein Y:Zr/Sc in the buffer layer decreases from up to essentially 100 at. % Y at the Si interface to down to essentially 0 at. % Y at the interface with the first layer with a continuous reduction in Y concentration therebetween. For example, the continuous reduction may be a substantially linear reduction in concentration.

Whilst the advantage of scandium oxide for graphene growth arises from its chemical stability, low surface energy and stability to roughening at high temperatures, and in particular its surface crystal orientation, without wishing to be bound by theory, it is also believed that the lattice constant for scandium oxide being a substantially precise multiple of that of graphene (i.e. 2.46 Å where 4×2.46 Å=9.84 Å) further assists in the formation of high quality graphene.

The buffer layer, when present, can be very thin and may have a thickness similar to that of the first layer of scandium oxide, e.g. a thickness of least 1 nm, preferably at least 2 nm, preferably at least 5 nm. Preferred ranges for the thickness of the buffer layer are from 1 nm to 50 nm, such as from 2 nm to 20 nm, more preferably up to 10 nm for thin buffer layers.

The present inventors unexpectedly found that a growth surface of a first layer formed of scandium oxide was surprisingly advantageous for graphene growth by CVD. Without wishing to be bound by theory, the inventors believe that scandium oxide has a particularly low carbon solubility at high temperatures (relative to known growth substrate materials) such that during the high temperatures of CVD, high-quality uniform graphene may be grown without the defects which can be present when grown directly on other known growth surfaces. For example, it is known that growth surfaces formed of materials such as silicon or III-V semiconductors can give rise to covalent bonding to the carbon atoms during growth resulting in graphene defects. The inventors were also surprised to find that the resulting graphene was yet further improved over similar oxides such as yttrium oxide or erbium oxide. Accordingly, the use of scandium oxide provides advantages for CVD grown graphene in terms of the resulting electronic properties, i.e. improved mobility, sheet resistance and Hall sensitivity.

CVD refers generally to a range of chemical vapour deposition techniques, each of which involve deposition to produce thin film materials such as two-dimensional crystalline materials like graphene. Volatile precursors, those in the gas phase or suspended in a gas, are decomposed to liberate the necessary species to form the desired material, carbon in the case of graphene. CVD as described herein is intended to refer to thermal CVD such that the formation of graphene from the decomposition of a carbon-containing precursor is the result of the thermal decomposition of said carbon-containing precursor.

Preferably, the method involves forming graphene by thermal CVD such that decomposition is a result of heating the carbon-containing precursor. Preferably, the temperature of the growth surface during CVD (i.e. wafer temperature) is from 700° C. to 1350° C., preferably from 800° C. to 1250° C., more preferably from 1000° C. to 1250° C. The inventors have found that such wafer temperatures are particularly effective for providing graphene growth directly on the materials described herein by CVD. Preferably, the CVD reaction chamber used in the method disclosed herein is a cold-walled reaction chamber wherein a heater coupled to the substrate is the only source of heat to the chamber.

As will be appreciated by those skilled in the art, the temperature setting input to some CVD reactors (i.e. set temperature) will generally be greater than the actual wafer temperature (such as with MOCVD reactors available from Aixtron®). The set temperature may be 100° C. (or more) greater than the wafer temperature, for example from 1,300° C. to 1,400° C. The wafer temperature may be measured using conventional techniques, for example using an optical probe. Other apparatuses may have a temperature feedback control whereby the reactor achieves the same wafer temperature as the input temperature (such as with high rotation rate MOCVD reactors available from Veeco®).

In a particularly preferred embodiment, the CVD reaction chamber comprises a close-coupled showerhead having a plurality, or an array, of precursor entry points. Such CVD apparatus comprising a close-coupled showerhead may be known for use in MOCVD processes. Accordingly, the method may alternatively be said to be performed using an MOCVD reactor comprising a close-coupled showerhead. In either case, the showerhead is preferably configured to provide a minimum separation of less than 100 mm, more preferably less than 25 mm, even more preferably less than 10 mm, between the surface of the substrate and the plurality of precursor entry points. As will be appreciated, by a constant separation it is meant that the minimum separation between the surface of the substrate and each precursor entry point is substantially the same. The minimum separation refers to the smallest separation between a precursor entry point and the substrate surface (i.e. the surface of the metal oxide layer). Accordingly, such an embodiment involves a “vertical” arrangement whereby the plane containing the precursor entry points is substantially parallel to the plane of the substrate surface (i.e. the growth surface).

The precursor entry points into the reaction chamber are preferably cooled. The inlets, or when used, the showerhead, are preferably actively cooled by an external coolant, for example water, so as to maintain a relatively cool temperature of the precursor entry points such that the temperature of the precursor as it passes through the plurality of precursor entry points and into the reaction chamber is less than 100° C., preferably less than 50° C. For the avoidance of doubt, the addition of precursor at a temperature above ambient does not constitute heating the chamber, since it would be a drain on the temperature in the chamber and is responsible in part for establishing a temperature gradient in the chamber.

Preferably, a combination of a sufficiently small separation between the substrate surface and the plurality of precursor entry points and the cooling of the precursor entry points, coupled with the heating of the substrate to with a decomposition range of the precursor, generates a sufficiently steep thermal gradient extending from the substrate surface to the precursor entry points to allow graphene formation on the substrate surface. As disclosed in WO 2017/029470, very steep thermal gradients may be used to facilitate the formation of high-quality and uniform graphene directly on non-metallic substrates, preferably across the entire surface of the substrate. The substrate may have a diameter of at least 5 cm (2 inches), at least 15 cm (6 inches) or at least 30 cm (12 inches). Particularly suitable apparatus for the method described herein include an Aixtron® Close-Coupled Showerhead® reactor and a Veeco® TurboDisk reactor.

Consequently, in a particularly preferred embodiment wherein the method of the present invention involves using a method as disclosed in WO 2017/029470, forming the graphene layer structure on the growth surface by CVD comprises:
providing the growth substrate on a heated susceptor in a close-coupled reaction chamber, the close-coupled reaction chamber having a plurality of cooled inlets arranged so that, in use, the inlets are distributed across the growth surface and have constant separation from the substrate;
cooling the inlets to less than 100° C. (i.e. so as to ensure that the precursor is cool as it enters the reaction chamber);
introducing a carbon-containing precursor in a gas phase and/or suspended in a gas through the inlets and into the close-coupled reaction chamber; and
heating the susceptor to achieve a growth surface temperature of at least 50° C. in excess of a decomposition temperature of the precursor, to provide a thermal gradient between the substrate surface and inlets that is sufficiently steep to allow the formation of graphene from carbon released from the decomposed precursor;
wherein the constant separation is less than 100 mm, preferably less than 25 mm, even more preferably less than 10 mm.

In another particularly preferred embodiment wherein the method involves using a method as disclosed in WO 2019/138231 (the contents of which is incorporated herein in its entirety), forming the graphene layer structure on the growth surface by CVD comprises:
providing the growth substrate on a heated susceptor in a reaction chamber, the reaction chamber having a plurality of inlets arranged so that, in use, the inlets are distributed across the growth surface and have constant separation from the substrate;
rotating the heated susceptor at a rotation rate of at least 600 rpm, preferably up to 3000 rpm;
introducing a carbon-containing precursor in a gas phase and/or suspended in a gas through the inlets and into the reaction chamber; and
heating the susceptor to achieve a growth surface temperature of at least 50° C. in excess of a decomposition temperature of the precursor;
wherein the constant separation is at least 12 cm, preferably up to 20 cm.

The most common carbon-containing precursor in the art for graphene growth is methane (CH₄). The inventors have found that it is preferable that the carbon-containing precursor used to form graphene is an organic compound, that is, a chemical compound, or molecule, that contains a carbon-hydrogen covalent bond, which comprises two or more carbon atoms. Such precursors have a lower decomposition temperature than methane which advantageously allows the growth of graphene at lower temperatures when using the method described herein which is particularly advantageous for growth on such non-metallic surfaces. Preferably, the precursor is a liquid when measured at 20° C. and 1 bar of pressure (i.e. under standard conditions according to IUPAC). Accordingly, the precursor has a melting point that is below 20° C., preferably below 10° C., and has a boiling point above 20° C., preferably above 30° C. Liquid precursors are simpler to store and handle when compared to gaseous precursors which typically require high pressure cylinders. Due to their relatively reduced volatility when compared to gaseous precursors, they present a lower safety risk during large scale manufacture. Increasing the molecular weight of the compounds beyond about C₁₀, particularly beyond about C₁₂, typically reduces their volatility and suitability for CVD growth of graphene on non-metallic substrates (though graphene can be produced from solid organic compounds). Preferably, the organic compound consists of carbon and hydrogen and, optionally, oxygen, nitrogen, fluorine, chlorine and/or bromine.

As discussed above, the method described herein preferably uses a carbon-containing precursor that is an organic compound comprising two or more carbon atoms, i.e. a C₂₊ organic compound. Preferably, the carbon-containing precursor is a C₃-C₁₂ organic compound consisting of carbon and hydrogen and, optionally, oxygen, nitrogen, fluorine, chlorine and/or bromine. As described herein, a Cₙ organic compound refers to one comprising “n” carbon atoms and optionally one or more further hetero atoms oxygen, nitrogen, fluorine, chlorine and/or bromine. Preferably, the organic compound comprises at most one heteroatom as such organic compounds are typically more readily available in high purity, for example ethers, amines, and haloalkanes.

The carbon-containing precursor is preferably a C₃-C₁₀ organic compound consisting of carbon and hydrogen and, optionally, oxygen, nitrogen, fluorine, chlorine and/or bromine, even more preferably a C₆-C₉ organic compound. In a preferred embodiment, the precursor does not comprise a heteroatom, such that the precursor consists of carbon and hydrogen. In other words, preferably the carbon-containing precursor is a hydrocarbon, preferably an alkane.

It is also preferable that the organic compound comprise at least two methyl groups (—CH₃). Particularly preferred organic compounds for use as carbon-containing precursors, and methods of forming graphene therefrom by CVD, are described in GB 2604377 (the contents of which is incorporated herein in its entirety). The inventors have found that when forming graphene directly on non-metallic substrates, precursors beyond the traditional hydrocarbons methane and acetylene allow for the formation of even higher quality graphene. Preferably, the precursor is a C₄-C₁₀ organic compound, more preferably the organic compound is branched such that the organic compound at least three methyl groups.

Without wishing to be bound by theory, the inventors believe that heavier organic compounds (i.e. those greater than C₁₂, or greater than C₁₀, and/or those which are solid under standard conditions) provide a “less pure” source of CH₃ radicals. With an increase in size and complexity of the organic compound there is an increase in the number of decomposition pathways and the possibility of a greater range of by-products which can lead to graphene defects. The organic compounds as described herein provide a balance of being large enough to deliver the required, and a desirably high fraction of, methyl groups under pyrolysis. The organic compounds are however small enough to be simple to purify, particularly where the precursor is liquid, and have a relatively simple pyrolysis chemistry with limited decomposition pathways. Furthermore, unlike heavier compounds, they do not so readily condense within the reactor plumbing which is a particular disadvantage for the industrial production of graphene due to the greater risk of reactor downtime.

Scandium oxide (and the other cubic oxides referred to herein for use in a buffer layer) are wide band gap materials, have high chemical inertness, high melting points, low vapour pressures and low surface energy. They also have high thermodynamic stability at the silicon interface against silicate and silicide formation which makes then highly favoured insulator layers for graphene epitaxy on silicon compared with other insulator materials. For example, fluorides can have low melting points and high vapour pressures and nitrides can have high surface energy which can make them less suitable.

In a particularly preferred embodiment of the present invention, the growth surface has a <111> crystallographic orientation. The crystallographic orientation of the growth surface depends on how the first layer orients on the substrate wafer as is known in the art. For example, a <111> growth surface of scandium oxide may be achieved through epitaxial growth on a <111> surface of a silicon wafer. Preferably, the support (in particular a silicon support) has a growth surface having a <111> or <100> crystallographic orientation for forming the first layer thereon. The inventors have found that a <111> orientation of the first layer is preferable for graphene epitaxy since it provides a lower energy orientation and is more stable to higher temperatures than <100>, for example. They were surprised to find that improved graphene crystallinity could be obtained on <111> which, without wishing to be bound by theory, is believed to result from the threefold rotational symmetry which lends itself to better growth of hexagonal two-dimensional crystals of graphene. Whilst silicon <111> may indirectly allow for higher quality graphene layer structures, silicon <100> is a cheaper support and a benefit may still be derived through use of the first layer as described herein.

Preferably, the method comprises annealing the growth substrate under nitrogen (N₂) prior to graphene formation, and the carbothermal reduction step when present. Such an anneal may be preferable to, for example, annealing under hydrogen (H₂) in which the inventors have observed a risk of current leakage between the resulting graphene and the silicon support layer. However, H₂ annealing has been observed to reconstruct the growth surface to provide a smooth planarised growth surface.

In some embodiments, it may be preferred that, prior to the step of forming the graphene layer structure on the growth surface of the first layer by CVD, the method comprises a step of carbothermally reducing the growth surface (that is, the method can comprise annealing the growth surface under a hydrocarbon (HC)). The inventors unexpectedly found that, prior to forming graphene on the growth surface of the first layer, exposure of the growth surface to a hydrocarbon at an elevated temperature results in a change in morphology to one more amenable to graphene epitaxy. Such a reconstruction of the surface is believed to be unique to scandium oxide when compared to other materials used extensively by the present inventors such as sapphire (aluminium oxide). Such as surface reconstruction occurs generally within the first 1 to 3 layers of atoms to provide an even lower surface energy. Such a reconstructed surface can be observed using SEM, TEM, electron diffractometry or preferably AFM.

The inventors have found that such a carbothermal surface reconstruction step can be carried out by heating the growth substrate under a minimal flow of hydrocarbon, i.e. under a flow rate of hydrocarbon that is insufficient to form graphene (a “sub-critical” flow rate). The temperature of such a step may be in the same range as that used for the subsequent graphene formation as described herein. The time required for such a surface reconstruction may be up to 8 hours, preferably up to 6 hours, for example from 1 to 8 hours, preferably from 2 to 6 hours. As such, the carbothermal reduction is preferably carried out in-situ in the reaction chamber directly before graphene formation, preferably wherein graphene is subsequently formed under a suitably increased flow rate of the hydrocarbon as a carbon-containing precursor (a “super-critical” flow rate). At greater times, the inventors have found that such a step risks undesirable <110> texturing of the growth surface. AFM may be used to reveal the emergence of threefold-rotated terraces. In some embodiments, graphene may be grown without a carbothermal reduction step (i.e. with no period of “sub-critical” flow rate) in order to mitigate and/or avoid texturing of the scandium oxide growth surface. As described herein, the inventors have also found that the use of a buffer layer is particularly effective at mitigating such texturing. Accordingly, in some preferred embodiments in which the first substrate further comprises a buffer oxide layer on the support layer, the method comprises a step of carbothermally reducing the growth surface.

The present invention also provides a graphene substrate comprising a CVD-grown graphene layer structure grown on the growth surface of a first layer on a support layer, the first layer formed of scandium oxide. The graphene being that grown directly on scandium oxide as disclosed herein by CVD therefore avoids physical transfer processing. The physical transfer of graphene, usually from copper substrates, introduces numerous defects which negatively impacts the physical and electronic properties of graphene. As such, a person skilled in the art can readily ascertain whether a graphene layer structure, and by extension a graphene substrate as described herein, is one comprising a CVD-grown graphene layer structure that has been grown directly on the specific materials using conventional techniques in the art such as atomic force microscopy (AFM), energy dispersive X-ray (EDX) spectroscopy, X-ray photoelectron spectroscopy (XPS) and preferably time-of-flight secondary ion mass spectrometry (ToF-SIMS). The graphene layer structure is devoid of copper contamination and devoid of transfer polymer residues by virtue of the complete absence of these materials in the process of obtaining the graphene substrate. Furthermore, such processing is not suitable for large scale manufacture (such as on CMOS substrates in fabrication plants). Unintentional doping, particularly from the catalytic metal substrates together with the etching solutions, also results in the production of graphene which is not sufficiently consistent from sample to sample as is required for commercial production.

As described herein with respect to the method of formation, it is preferred that the surface of the first layer formed of scandium oxide has a crystallographic orientation of <111> which may then be said to be in contact with the graphene layer structure (such that there are no intervening layers).

In accordance with a further aspect of the present invention, there is provided an electronic device comprising the graphene substrate as described herein. As will be appreciated, the graphene layer structure of the graphene substrate may be patterned using known techniques and electrical contacts may be provided so as to enable the substrate to be incorporated into an electronic device. That is, an electronic device may be manufactured from a graphene substrate thereby incorporating a graphene layer structure directly on a scandium oxide layer, said scandium oxide layer on a support layer as described herein. Further steps for forming electronic devices are known in the art and may include patterning, such as by photolithography, laser and/or plasma etching, and/or deposition of additional layers and materials such as dielectric layers and/or metal ohmic contacts. The electronic device may be diced from an array of devices formed simultaneously from a larger graphene substrate.

An electronic device comprising such a graphene substrate (i.e. comprising graphene grown directly on a first layer) may be improved over prior art devices in view of the advantageous properties afforded by the graphene, in particular an improvement in carrier mobility. Photonic devices are preferable, for example, an electro-optic modulator is one preferred electronic device which may benefit from greater carrier mobility. In particular, an electro-optic modulator comprising the graphene substrate may operate with greater bandwidth. Other preferred electronic devices include transistors (i.e. graphene transistors) such as radio frequency graphene field effect transistors (RF GFETs) which rely on high carrier mobilities to switch “on” and “off” at such high frequencies. Biosensors are also preferred electronic devices which benefit from the higher mobility of graphene due to the associated reduction in sheet resistance which reduces the power required for operation. Another particularly preferred electronic device is a Hall effect sensor. The sensitivity of such devices may be improved with higher carrier mobilities.

The present invention is particularly advantageous for photonic devices due to the need to integrate graphene on silicon wafers such that a photonic device could be manufactured using the resulting graphene substrate and processed using industry-standard silicon tools.

There is also described herein a further aspect of the present invention that is a method of forming a graphene layer structure, the method comprising:
providing a growth substrate comprising a first layer on a support layer; and
forming a graphene layer structure on a growth surface of the first layer by CVD;
wherein the first layer is formed of aluminium gallium oxide (AGO).

The description provided herein with respect to the first layer being formed of scandium oxide may apply equally to this further aspect unless the context clearly dictates otherwise. For example, it is preferred that the growth surface of the first layer formed of AGO has a <111> crystallographic orientation. The growth substrate may comprise a buffer layer between the support layer and first layer, particularly wherein the support layer is formed of silicon. In this further aspect, together with the materials described for a buffer layer in respect of the first aspect, the material for the buffer layer can include scandium oxide. For example, it is preferred that the growth substrate comprises a buffer oxide layer, such as a buffer oxide layer formed of erbium oxide, yttrium oxide, scandium oxide or a combination thereof. Similarly, the description provided herein of the CVD process, and the corresponding apparatus features of reactors, are also particularly suitable for this further aspect. Aluminium gallium oxide may alternatively be known to be represented by the formula (AlGa)₂O₃. Such a layer may be formed on a support layer (or buffer layer) to provide the growth substrate by MBE or sputtering as described herein, though may also be formed by CVD or ALD.

### FIGURES

The present invention will now be described further with reference to the following non-limiting Figures, in which:

FIG. 1 illustrates an embodiment of the method of the present invention.

FIG. 2 illustrates an embodiment of the graphene substrate of the present invention.

FIG. 3 is an AFM image of the scandium oxide surface of a growth substrate.

FIG. 4 is an AFM image of the scandium oxide surface of a growth substrate after an anneal under N₂.

FIG. 5 is an AFM image of the scandium oxide surface of a growth substrate after an anneal under H₂.

FIG. 6 is an AFM image of the reconstructed scandium oxide surface of a growth substrate after a carbothermal reduction step under a sub-critical hydrocarbon flow.

FIG. 7 is an AFM image of a graphene substrate formed by CVD growth of graphene on an untreated scandium oxide surface of a growth substrate.

FIG. 8 is an AFM image of a graphene substrate formed by CVD growth of graphene on the reconstructed scandium oxide surface of the growth substrate shown in FIG. 6.

FIG. 9 is an AFM image of a graphene substrate formed by CVD growth of graphene on a scandium oxide surface of a growth substrate.

FIG. 10 is an AFM image of a graphene substrate formed by CVD growth of graphene on a scandium oxide surface of a growth substrate comprising an yttrium oxide buffer layer.

FIGS. 11-13 are AFM images of a graphene substrate formed by CVD growth of graphene on a scandium oxide surface of various growth substrates comprising an erbium oxide buffer layer.

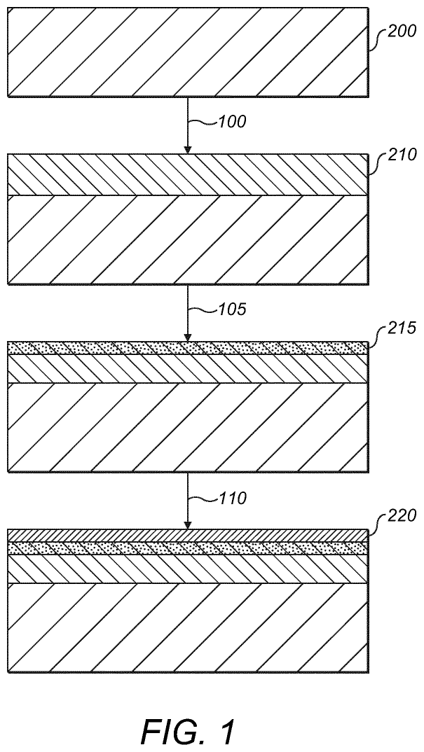

FIG. 1 illustrates an exemplary embodiment of the method of the present invention. The method comprises providing a silicon substrate/wafer 200 to be a support layer of a substrate for graphene growth. The silicon wafer 200 has a <111> crystallographic orientation upon which, in a first step 100, a first layer 210 formed of scandium oxide (Sc₂O₃) is formed epitaxially by high temperature sputtering to a thickness of between 10 and 50 nm (e.g. about 40 nm). The first layer 210 provides a growth surface having a <111> crystallographic orientation.

The substrate consisting of the silicon wafer 200 and first layer 210 is loaded into a CVD reaction chamber whereupon the substrate is treated in a carbothermal reduction step 105 under a sub-critical flow of carbon-containing gas, generally a hydrocarbon (e.g. methane or hexane), for example for about 4 hours at a temperature between 800° C. and 1,250° C. The uppermost atomic layers of the first layer are reconstructed under these conditions to provide a lower energy reconstructed growth surface 215.

In the same reaction chamber, the flow rate of the carbon-containing gas is increased to a super-critical flow rate so as to produce graphene 220 on the growth surface of the scandium oxide 210/215 by CVD in step 110.

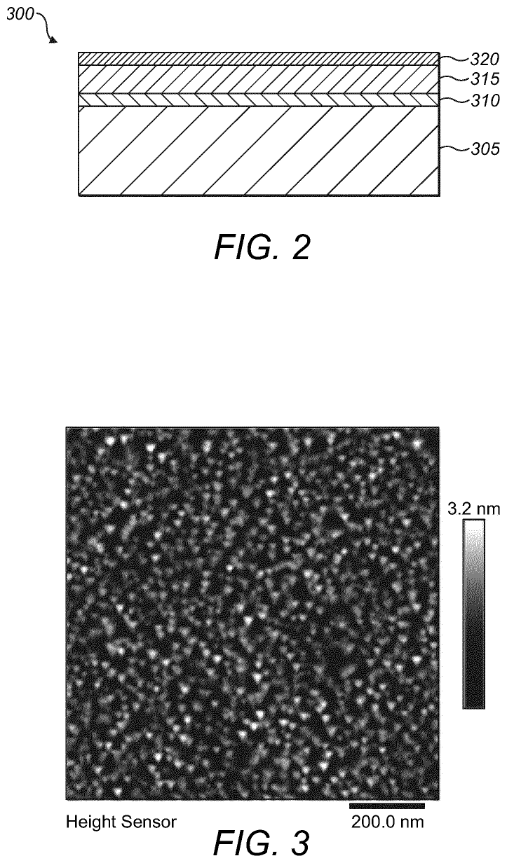

FIG. 2 illustrates an exemplary preferred embodiment of a graphene substrate 300 of the present invention. The graphene substrate 300 comprises a CVD-grown graphene layer structure 320 grown directly on a <111> surface of a scandium oxide layer 315 of a growth substrate, wherein the growth substrate comprises the scandium oxide layer 315 directly on a buffer layer 310 which is itself provided directly on a silicon support layer 305. In preferred embodiments, the buffer layer 310 is a buffer oxide layer, for example formed of yttrium oxide or erbium oxide.

### EXAMPLES

### Example 1

There is a need in the art for processes which enable the growth of high quality graphene on silicon wafers for the integration of graphene into standard silicon based microelectronic processing of electronic devices. The inventors have sought to overcome the problems associated with growth on silicon wafers through the use of additional buffer layers between the silicon wafer and the graphene. However, it is essential that these layers be suitable for the growth of graphene at the high temperatures required for CVD whilst also being stable as a thin film on silicon. The inventors identified rare earth oxides as having, in principle, the qualities required. Such materials can be formed with good crystal quality and low surface roughness without melting or desorbing at CVD temperatures. They are relatively unreactive to silicon and have stable crystalline phases and, crucially, have relatively low surface energies.

The inventors investigated the growth of graphene by CVD (in accordance with the method disclosed in WO 2017/029470) on silicon wafers having a layer a growth surface provided by epitaxially grown rare earth oxides.

Table 1 below provides data for some of these experiments for graphene grown on yttrium oxide, scandium oxide and erbium oxide, on silicon. An additional comparison for graphene grown on aluminium nitride on silicon is also provided.

TABLE 1

| Growth substrate | | Peak mobility | Sheet |
|---|---|---|---|
| (first layer/ | Mobility | (close to | resistance |
| support | (at N~1e13 cm⁻²) | Dirac point) | (as-grown) |
| layer) | (cm²/Vs) | (cm²/Vs) | (Ω/□) |
| Sc₂O₃/Si | 400 | 2,300 | 800 |
| Y₂O₃/Si | 60 | 100 | 3,500 |
| Er₂O₃/Si | n/a | n/a | 6,000 |
| AlN/Si | 180 | 180 | 3,000 |

The inventors found that growth on yttrium oxide and erbium oxide was challenging despite the expected advantages of rare earth oxides. Growth of graphene was found to require generally higher temperatures and higher flow rates of precursor in order to ‘force’ nucleation of carbon on the surface. However, significant secondary nucleation, and wrinkles around the edges of nuclei, leading to poorer graphene quality could be observed. The 2D peak in the Raman spectra for Y and Er oxides was weak whereas it was much sharper and clearer when grown on Sc oxide. These results demonstrate the unexpected result that scandium oxide was significantly superior to other rare earth oxides in allowing for the growth of graphene having desirably high mobility and low resistivity.

### Example 2

A first layer formed of Sc₂O₃ <111> was deposited on and across a silicon wafer/support epitaxially by high temperature sputtering to a thickness of about 40 nm. An AFM image of the resulting scandium oxide surface is shown in FIG. 3.

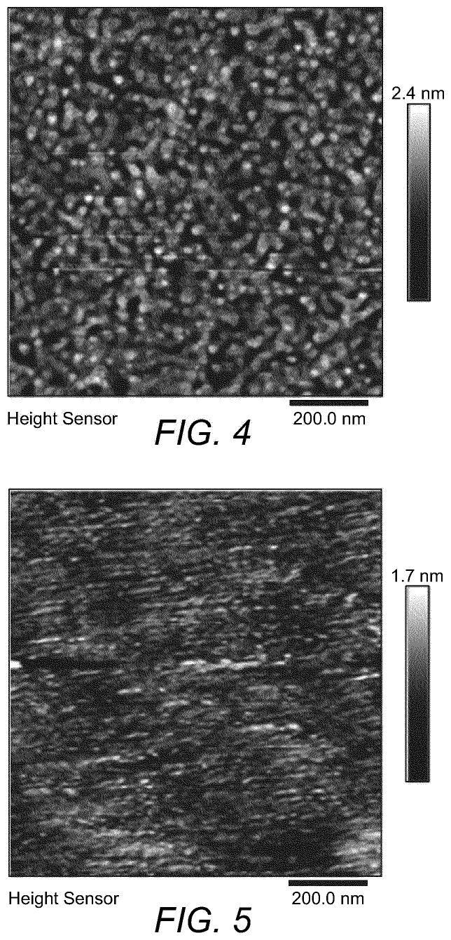

Annealing of a Sc₂O₃ <111> surface in nitrogen was performed for 9,600 s in an MOCVD reactor at a set heater temperature of 1,300° C., under a nitrogen flow of 60 slm at 30 mbar. The resulting growth substrate was then cooled to room temperature under a flow of 60 slm nitrogen at 30 mbar. An AFM image of the resulting scandium oxide surface is shown in FIG. 4.

Annealing of a Sc₂O₃ <111> surface in hydrogen was performed for 1,800 s in an MOCVD reactor at a set heater temperature of 1,260° C., under a hydrogen flow of 60 slm at 100 mbar. The resulting growth substrate was then cooled to room temperature under a flow of 60 slm nitrogen at 30 mbar. An AFM image of the resulting scandium oxide surface is shown in FIG. 5.

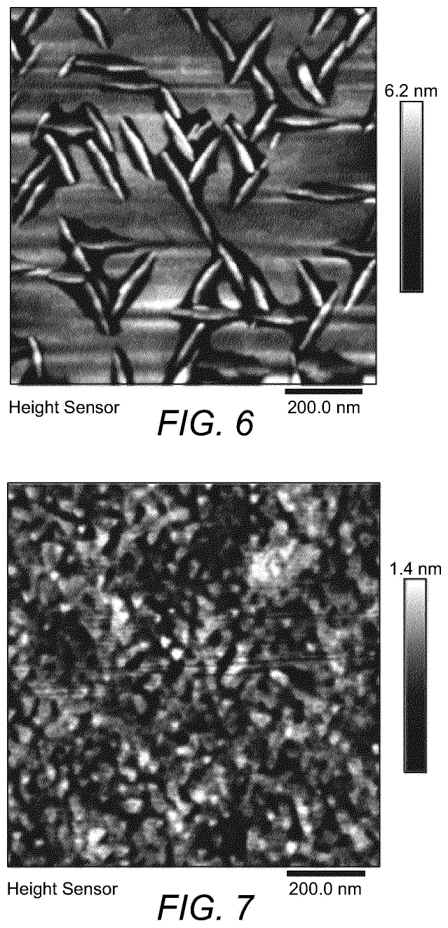

Annealing of a Sc₂O₃ <111> surface in sub-critical hydrocarbon pressure was performed for 15,000 s in an MOCVD reactor at a set heater temperature of 1,300° C., under a combined hydrocarbon and nitrogen flow of 60 slm at 30 mbar. The resulting growth substrate was then cooled to room temperature under a flow of 60 slm nitrogen at 30 mbar. An AFM image of the resulting scandium oxide surface is shown in FIG. 6.

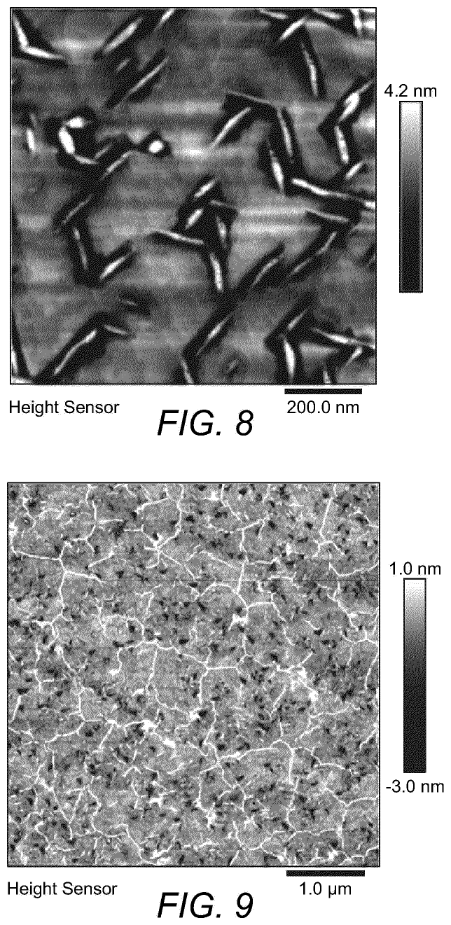

After the annealing of the Sc₂O₃ <111> surface in a sub-critical pressure of hydrocarbon, graphene was grown in the MOCVD reactor by first annealing the surface in a 60 slm flow of nitrogen at 400 mbar at a set temperature of 1,150° C. for 600 s. The set temperature was then increased to 1,300° C. and hydrocarbon was re-introduced to the chamber at a super-critical flow rate to form a graphene monolayer. The wafer was then cooled to room temperature under a flow of 60 slm nitrogen at 30 mbar. An AFM image of the surface of the resulting graphene substrate is shown in FIG. 8. Graphene growth without the prior anneal in sub-critical hydrocarbon pressure was performed under the same conditions and an AFM image of the surface of the resulting graphene substrate is shown in FIG. 7.

FIG. 4 is an AFM image of the scandium oxide surface of a growth substrate after the anneal under N₂ and shows little modification in the surface morphology when compared to the as-prepared growth substrate as shown in FIG. 3. On the other hand, annealing of scandium oxide surface under reducing conditions results in significant reconstruction of the surface. For H₂ annealing, there is a clear conversion from the 3D pyramidal morphology to a flat, planarised surface as shown in FIG. 5.

FIG. 6 is the AFM image of the reconstructed scandium oxide surface of a growth substrate after the carbothermal reduction step under the sub-critical hydrocarbon flow. Annealing under a “sub-critical” hydrocarbon flow (i.e. below the nucleation rate for graphene growth, where the hydrocarbon is a reducing agent) results in both planarisation and the emergence of vertically-aligned platelets (i.e. terraces or texturing) with a threefold rotational symmetry which reflects that of the <111> substrate.

FIGS. 7 and 8 are AFM images of graphene substrates formed by CVD growth of graphene on the untreated scandium oxide surface and the carbothermally reduced and reconstructed surface, respectively. Growth on the hydrocarbon-reconstructed surface results in graphene with a sheet resistance below half that of graphene grown on surface without the prior reconstruction treatment, i.e. 1,600Ω/□ and 3,400Ω/□, respectively, and a greater mobility of 235 cm²/Vs compared to 160 cm²/Vs. Likewise the Raman defect peak height ratio D/G was also observed to have been halved.

### Example 3

A first layer formed of Sc₂O₃ <111> was deposited on and across a <111> surface of a silicon wafer/support epitaxially by MBE to a thickness of about 38 nm. The surface was annealed under nitrogen for 600 s at 400 mbar in an MOCVD reactor at a set heater temperature of 1,150° C. A graphene monolayer was then grown on the scandium oxide surface in the MOCVD reactor. An AFM image of the surface of the resulting graphene substrate is shown in FIG. 9.

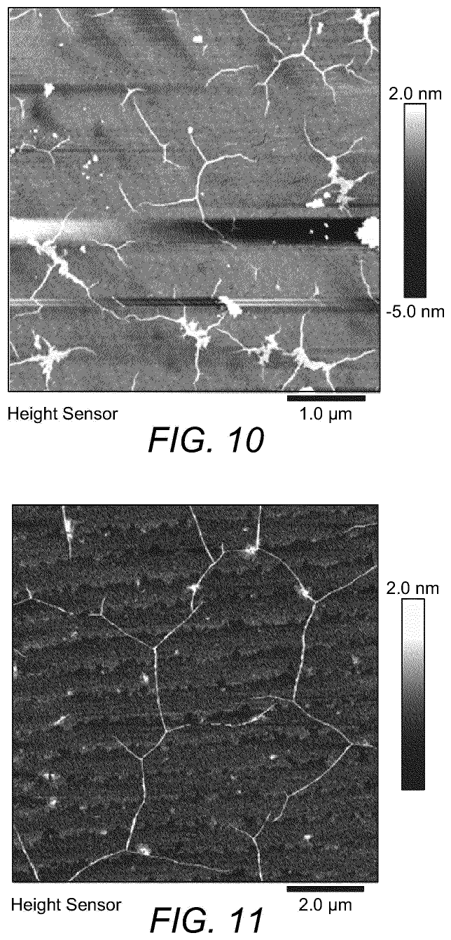

A buffer layer formed of yttrium oxide <111> was deposited on and across a <111> surface of a silicon wafer/support epitaxially by MBE to a thickness of about 6 nm. A first layer formed of Sc₂O₃ <111> was deposited on and across the buffer layer epitaxially by MBE to a thickness of about 28 nm. The surface was then annealed under nitrogen as described above and a graphene monolayer was grown on the scandium oxide surface in the MOCVD reactor. An AFM image of the surface of the resulting graphene substrate is shown in FIG. 10.

A buffer layer formed of erbium oxide <111> was deposited on and across a <111> surface of a silicon wafer/support epitaxially by MBE to a thickness of about 5 nm. A first layer formed of Sc₂O₃ <111> was deposited on and across the buffer layer epitaxially by MBE to a thickness of about 30 nm. The surface was then annealed under nitrogen as described above and a graphene monolayer was grown on the scandium oxide surface in the MOCVD reactor. An AFM image of the surface of the resulting graphene substrate is shown in FIG. 11.

When compared the graphene formed on a first layer of scandium oxide without use of a buffer layer, the AFM results in FIGS. 10 and 11 demonstrate that a much smoother graphene monolayer is obtained. A lower wrinkle density is achieved and there is reduced pitting when compared to the AFM image in FIG. 9 providing evidence that the cube-on-cube stacking at the buffer oxide/silicon interface with a strained scandium oxide growth surface may be more stable than a domain matched relaxed first layer of scandium oxide formed directly on silicon.

### Example 4

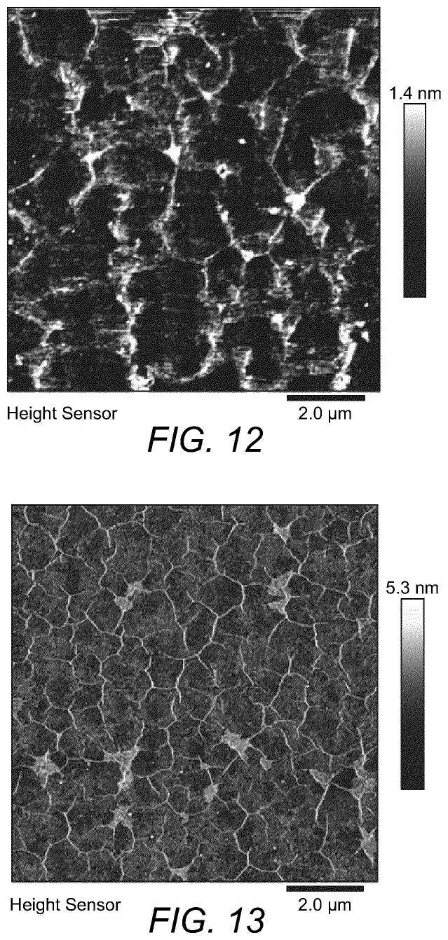

The erbium oxide sample in Example 3 was repeated twice with a scandium oxide first layer thickness of about 80 nm and about 120 nm (in combination with an erbium oxide layer having a thickness of about 5 nm). The graphene monolayer grown thereon was then analysed by Raman spectroscopy and the results summarised in Table 2. An AFM image of the surface of the resulting graphene substrates for 80 nm and 120 nm scandium oxide are shown in FIGS. 12 and 13, respectively.

TABLE 2

| Scandium oxide | | | |
|---|---|---|---|
| thickness (nm) | D/G | 2D/G | G(FWHM) |
| 30 | 0.90 | 4.48 | 13.3 |
| 80 | 0.95 | 4.77 | 15.7 |
| 120 | 1.00 | 4.83 | 18.8 |

The above Raman parameters are well-known in the art for characterising graphene. The ratio of D/G can be referred to as a disorder ratio whereby it is preferred to minimise the value, whereas a greater ratio of 2D/G is preferred as characteristic of a two-dimensional material. The inventors have found that there is a positive correlation between the graphene sheet resistance and the full-width-half-maximum of the G band such that the G (FWHM) is also preferably minimised.

The above results demonstrate that whilst a marginal increase in D/G is observed with increasing thickness of scandium oxide, an increase in the 2D/G ratio is obtained. At least in part, this in turn leads to an increase in the G (FWHM) due to the larger G band. The data shows that texturing of the scandium oxide surface becomes more apparent at greater thicknesses since the thicker layer is more relaxed (akin to that observed when using scandium oxide on a support without a buffer layer), as can be seen in the corresponding AFM images 11-13. Accordingly, it is particularly advantageous to use a combination of a buffer layer with thin scandium oxide.

### Example 5

The erbium oxide sample in Example 3 was repeated twice with an erbium oxide buffer layer having a thickness of about 2 nm and about 10 nm (in combination with a scandium oxide layer having a thickness of about 30 nm). The graphene monolayer grown thereon was then analysed by Raman spectroscopy and the results summarised in Table 3.

TABLE 3

| Erbium oxide | | | |
|---|---|---|---|
| thickness (nm) | D/G | 2D/G | G(FWHM) |
| 2 | 0.43 | 4.81 | 11.5 |
| 5 | 0.90 | 4.48 | 13.3 |
| 10 | 0.99 | 3.55 | 14.2 |

The above results demonstrate that by decreasing the thickness of the buffer layer, there is a strong decrease in the D/G ratio and increase in the 2D/G ratio. Furthermore, there is a decrease in the G (FWHM) which can allow for reduced sheet resistance. As such, very thin buffer layers, in particular very thin erbium oxide, can be especially advantageous for providing higher quality graphene. Use of a buffer layer may also result in higher peak mobility (and at higher carrier concentration). The inventors have found that graphene may be grown with lower defect density, which in turn has been found to substantially reduce the rate of air doping.

As used herein, the singular form of “a”, “an” and “the” include plural references unless the context clearly dictates otherwise. The use of the term “comprising” is intended to be interpreted as including such features but not excluding other features and is also intended to include the option of the features necessarily being limited to those described. In other words, the term also includes the limitations of “consisting essentially of” (intended to mean that specific further components can be present provided they do not materially affect the essential characteristic of the described feature) and “consisting of” (intended to mean that no other feature may be included such that if the components were expressed as percentages by their proportions, these would add up to 100%, whilst accounting for any unavoidable impurities), unless the context clearly dictates otherwise.

Numerical lower and upper limits of features described herein may preferably be combined to provide a closed range.

It will be understood that, although the terms “first”, “second”, etc. may be used herein to describe various elements, layers and/or portions, the elements, layers and/or portions should not be limited by these terms. These terms are only used to distinguish one element, layer or portion from another, or a further, element, layer or portion. It will be understood that the term “on” is intended to mean “over” such that there may or may not be intervening layers between one material being said to be “on” another material (e.g. a buffer layer). Unless the context clearly dictates otherwise, “on” preferably means “directly on” such that there are no intervening layers. Spatially relative terms, such as “below”, “beneath”, “lower”, “above”, “upper” and the like, may be used herein for ease of description to describe one element or feature's relationship to another element(s) or feature(s). It will be understood that the spatially relative terms are intended to encompass different orientations of the substrate or device in use or operation in addition to the orientation depicted in the figures. For example, if the substrate in the figures is turned over, elements described as “below” or “beneath” other elements or features would then be oriented “above” the other elements or features. Thus, the example term “below” can encompass both an orientation of above and below. The substrate may be otherwise oriented and the spatially relative descriptors used herein interpreted accordingly.

The foregoing detailed description has been provided by way of explanation and illustration, and is not intended to limit the scope of the appended claims. Many variations of the presently preferred embodiments illustrated herein will be apparent to one of ordinary skill in the art, and remain within the scope of the appended claims and their equivalents.

1. A method of forming a graphene layer structure, the method comprising:
providing a growth substrate comprising a first layer on a support layer; and
forming a graphene layer structure on a growth surface of the first layer by CVD;
wherein the first layer is formed of scandium oxide.

2. The method according to claim 1, wherein the growth surface has a <111> crystallographic orientation.

3. The method according to claim 1, wherein the support layer comprises silicon.

4. The method according to claim 1, wherein the temperature of the growth surface during CVD is from 700° C. to 1350° C.

5. The method according to claim 1, wherein forming the graphene layer structure on the growth surface by CVD comprises:
providing the growth substrate on a heated susceptor in a close-coupled reaction chamber, the close-coupled reaction chamber having a plurality of cooled inlets arranged so that, in use, the inlets are distributed across the growth surface and have constant separation from the substrate;
cooling the inlets to less than 100° C.;
introducing a carbon-containing precursor in a gas phase and/or suspended in a gas through the inlets and into the close-coupled reaction chamber; and
heating the susceptor to achieve a growth surface temperature of at least 50° C. in excess of a decomposition temperature of the precursor, to provide a thermal gradient between the substrate surface and inlets that is sufficiently steep to allow the formation of graphene from carbon released from the decomposed precursor;
wherein the constant separation is less than 100 mm.

6. The method according to claim 1, wherein forming the graphene layer structure on the growth surface by CVD comprises:
providing the growth substrate on a heated susceptor in a reaction chamber, the reaction chamber having a plurality of inlets arranged so that, in use, the inlets are distributed across the growth surface and have constant separation from the substrate;
rotating the heated susceptor at a rotation rate of at least 600 rpm;
introducing a carbon-containing precursor in a gas phase and/or suspended in a gas through the inlets and into the reaction chamber; and
heating the susceptor to achieve a growth surface temperature of at least 50° C. in excess of a decomposition temperature of the precursor;
wherein the constant separation is at least 12 cm.

7. The method according to claim 1, wherein the graphene layer structure is a graphene monolayer.

8. The method according to claim 1, wherein the first layer has a thickness of from 2 nm to 500 nm.

9. The method according to claim 1, wherein the CVD growth of the graphene layer structure involves the use of a hydrocarbon precursor.

10. The method according to claim 1, wherein the growth substrate is provided by forming the first layer by epitaxy on a first substrate comprising the support layer.

11. The method according to claim 10, wherein the first substrate consists of the support layer, and wherein the first layer is formed by epitaxy directly on the first substrate.

12. The method according to claim 10, wherein the first substrate further comprises a buffer oxide layer on the support layer, and wherein the first layer is formed by epitaxy directly on the buffer oxide layer.

13. The method according to claim 12, wherein the buffer oxide layer is formed of erbium oxide, yttrium oxide, zirconium oxide, yttria-stabilised zirconia or a combination thereof.

14. The method according to claim 1, wherein prior to the step of forming the graphene layer structure on the growth surface of the first layer by CVD, the method comprises a step of annealing the growth surface under nitrogen, hydrogen or hydrocarbon.

15. A graphene substrate comprising a CVD-grown graphene layer structure grown directly on a first layer of a growth substrate, wherein the growth substrate comprises the first layer on a support layer, and wherein the first layer is formed of scandium oxide.

16. The graphene substrate according to claim 15, wherein the first layer has a surface contacting the graphene layer structure having a <111> crystallographic orientation.

17. The graphene substrate according to claim 15, wherein the first layer is directly on the support layer.

18. The graphene substrate according to claim 15, wherein the first layer is directly on a buffer oxide layer, and wherein the buffer oxide layer is directly on the support layer.

19. The graphene substrate according to claim 18, wherein the buffer oxide layer is formed of erbium oxide, yttrium oxide, zirconium oxide, yttria-stabilised zirconia or a combination thereof.

20. The graphene substrate according to claim 15, obtainable by the method of claim 1.

21. An electronic device comprising the graphene substrate according to claim 15.
